(19) United States
(12) Patent Application Publication
(10) Pub. No.: US 2008/0088001 A1
(43) Pub. Date: Apr. 17, 2008

(54) Package on package and method thereof

(75) Inventors: Tae-hun Kim, Cheonan-si (KR); Sung-yong Park, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/898,226

(22) Filed: Sep. 11, 2007

(30) Foreign Application Priority Data
Sep. 11, 2006 (KR) 10-2006-0087425

(51) Int. Cl. H01L 23/488; H01L 21/58

(52) U.S. Cl. 257/686; 438/109; 257/E23.023; 257/E21.505

(57) ABSTRACT

A package on package (POP) and method thereof are provided. The example POP may include a first semiconductor package including a first substrate, the first substrate being a flexible substrate having at least one folded portion, a first semiconductor chip mounted on and electrically connected to the first substrate and a second semiconductor package including a second substrate, at least one second semiconductor chip mounted on and electrically connected to the first substrate, the first and second semiconductor packages being electrically connected between the at least one folded portion of the first substrate and a portion of the second substrate.

### PRIORITY STATEMENT

This application claims the benefit of Korean Patent Application No. 10-2006-0087425, filed on Sep. 11, 2006, in the Korean Intellectual Property Office, the disclosure of which is incorporated herein in its entirety by reference.

### BACKGROUND

1. Field

Example embodiments relate generally to a package on package (POP) and method thereof.

2. Description

A conventional semiconductor package may include structures such as a system in package (SIP), a package on package (POP) and a multi-chip package (MCP). The SIP is a semiconductor package integrating a number of conventional semiconductor packages into a single semiconductor package. SIPs may conventionally be produced in one of two ways. In a first conventional SIP process, a number of semiconductor chips may be stacked in a single semiconductor package so as to form an MCP. In a second conventional SIP process, a number of semiconductor packages may be stacked to form a POP after each individual semiconductor package undergoes discrete packaging and electrical testing.

FIG. 1 is a sectional view illustrating a conventional POP.

Referring to FIG. 1, a lower semiconductor package 10 and an upper semiconductor package 20 may be prepared, and packaging and electrical testing may be individually (e.g., separately) performed on the lower and upper semiconductor packages. Solder balls 12 may be formed on a lower surface of a body in the lower semiconductor package 10, and solder ball pads 14 may be formed on an upper surface thereof to be connected to the upper semiconductor package 20. Solder balls 22 may be formed on a lower surface of a body in the upper semiconductor package 20, such that the upper semiconductor package 20 may be electrically connected to the lower semiconductor package 10 via the solder balls 22.

Generally, as a conventional semiconductor package becomes thinner, warpage defects in a body of the semiconductor package may become more likely. The warpage defect, which may occur during the stacking of the upper semiconductor package 20 and the lower semiconductor package 10, may cause a solder non-wet defect, in which the solder ball 22 of the upper semiconductor package 20 may not be sufficiently connected to the solder ball pad 14 of the lower semiconductor package 10.

Solder non-wet defects may degrade the production yield of a conventional POP manufacturing process. Further, because the solder non-wet defect may conventionally be generated after testing has been separately performed on the discrete semiconductor package, another round of testing may be performed after the detection of a solder non-wet defect, which may increase the costs of manufacturing conventional POPs.

### SUMMARY OF EXAMPLE EMBODIMENTS

An example embodiment is directed to a package on package (POP), including a first semiconductor package including a first substrate, the first substrate being a flexible substrate having at least one folded portion, a first semiconductor chip mounted on and electrically connected to the first substrate and a second semiconductor package including a second substrate, at least one second semiconductor chip mounted on and electrically connected to the first substrate, the first and second semiconductor packages being electrically connected between the at least one folded portion of the first substrate and a portion of the second substrate.

Another example embodiment is directed to a method of fabricating a POP, including folding at least one portion of a first substrate within a first semiconductor package including a first semiconductor chip, the first substrate being a flexible substrate, mounting a second semiconductor package on the first semiconductor package, the second semiconductor package including a second substrate and at least one second semiconductor chip and forming an electrical connection between the first and second semiconductor packages via the at least one folded portion of the first substrate and a portion of the second substrate.

Another example embodiment is directed to a POP for reducing an occurrence of a solder non-wet defect in stacked semiconductor packages.

### BRIEF DESCRIPTION OF THE DRAWINGS

Detailed illustrative example embodiments are disclosed herein. However, specific structural and functional details disclosed herein are merely representative for purposes of describing example embodiments. Example embodiments may, however, be embodied in many alternate forms and should not be construed as limited to the embodiments set forth herein.

FIG. 1 is a sectional view illustrating a conventional package on package (POP).

FIGS. 2 through 11 are views illustrating a process of fabricating a package on package (POP) according to an example embodiment.

FIG. 12 is a sectional view illustrating a POP according to another example embodiment. modified example of FIG. 11;

FIG. 13 is a sectional view illustrating a modification to the structure of FIG. 6 according to another example embodiment.

FIG. 14 is a sectional view illustrating a modification to the structure of FIG. 9 according to another example embodiment.

FIG. 15 is a sectional view illustrating a semiconductor package according to another example embodiment.

FIG. 16 is a sectional view illustrating another semiconductor package according to another example embodiment.

FIG. 17 is a sectional view illustrating that a POP according to another example embodiment.

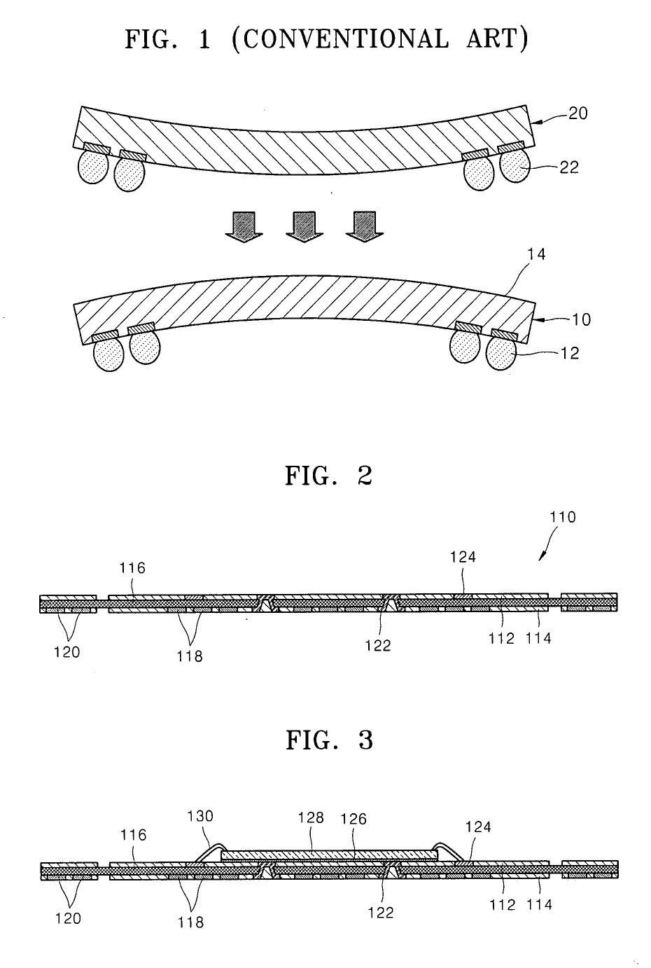

### DETAILED DESCRIPTION OF EXAMPLE EMBODIMENTS

Detailed illustrative example embodiments are disclosed herein. However, specific structural and functional details disclosed herein are merely representative for purposes of describing example embodiments. Example embodiments may, however, be embodied in many alternate forms and should not be construed as limited to the embodiments set forth herein.

Accordingly, while example embodiments are susceptible to various modifications and alternative forms, specific embodiments thereof are shown by way of example in the drawings and will herein be described in detail. It should be understood, however, that there is no intent to limit example embodiments to the particular forms disclosed, but conversely, example embodiments are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIGS. 2 through 11 are views illustrating a process of fabricating a package on package (POP) according to an example embodiment.

In the example embodiment of FIG. 2, a bond finger 124, which may be used as a connection terminal for wire bonding, may be formed on an upper surface of a substrate 110. A solder ball pad 118, to which a solder ball may be attached, may be formed on a lower surface of the substrate 110. The remaining portions of the upper and lower surfaces of the substrate 110 may be covered with photo solder resist (PSR) 112 and 114 (e.g., which may be used for insulation).

In the example embodiment of FIG. 2, in an example, given portions of each edge of the substrate 110 need not be covered with PSR, and solder ball pads 120 may be formed on the lower surface of the substrate edges to be folded. In FIG. 2, a reference numeral 116 may represent a substrate base including an insulating substrate and two or more layered-printed circuit patterns, and a reference numeral 122 may represent a through hole.

In the example embodiment of FIG. 3, a semiconductor chip 128 used for a lower semiconductor package may be mounted on the substrate 110 using an adhesive 126. In an example, the adhesive may be liquid epoxy (e.g., either non-conductive or conductive) and/or an adhesive tape. In an example, the semiconductor chip 128 may be a semiconductor chip performing a logic function. A wire bonding may be performed to electrically connect the bond pad of the semiconductor chip 128 and the bond finger 124 of the substrate 110 using a wire 130.

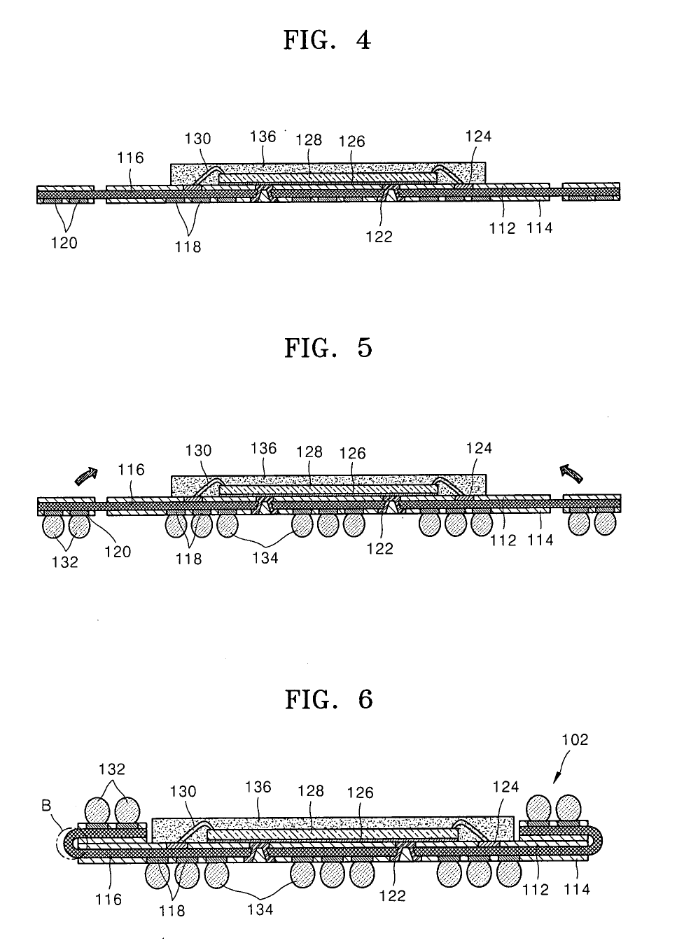

In the example embodiment of FIG. 4, a molding process may be performed to seal the semiconductor chip 128, the wire 130, and a portion of the upper surface of the substrate 110 on the resultant structure after the wire bonding is completed. In an example, a sealing resin 136 used for the molding process may be thermoset, resin such as epoxy mold compound (EMC). In an example, the sealing resin 136 need not cover the entire upper surface of the substrate 110, but rather may be formed only on a portion other than the folded portions of the substrate 110.

In the example embodiment of FIG. 5, a solder ball may be attached to the resultant structure after the molding process. In an example, solder balls 134 may be attached to the lower surface of the substrate 110, which may not be folded, and solder balls 132 may also be attached to the lower surface of the substrate 110, which may be folded. The edges of the substrate 110 may then be respectively bent toward the directions indicated by arrows as shown in FIG. 5.

In the example embodiment of FIG. 6, the folded portions of the substrate 110 may be bent horizontally, such that the folded portions of the substrate 110 may be attached to each other. In an example, the attachment of the folded portions of the substrate 110 may be made using one of an insulating liquid adhesive and bonding tape, or alternatively a conductive liquid adhesive and bonding tape. Thus, the portions of the substrate base 116, on which an insulating material and two or more-layered printed circuit patterns may be disposed, indicated by a reference letter B may be bent and folded.

In the example embodiment of FIG. 6, additional PSRs 112 and 114 may not be formed at the portions B in which the substrate base 116 are folded (e.g., at 180°) (e.g., because cracks may occur at the PSRs 112 and 114 if the substrate 110 is horizontally folded). Thus, moisture penetration may be reduced because an occurrence of cracks may be reduced.

In the example embodiment of FIG. 6, a reliability test may be performed on the POP to determine whether deterioration of the reliability (e.g., a pressure pot) has occurred, which may accelerate a deterioration of functions of the POP due to any present moisture penetration. In the pressure pot, a semiconductor package may be placed in a sealed pot with a higher humidity and a higher pressure for a given amount of time, and the functions of the semiconductor package may be reexamined. Thus, if cracks occur in the PSRs 112 and 114, moisture may penetrate through into the cracks, which may cause printed circuit patterns in proximity to the moisture penetration to rust.

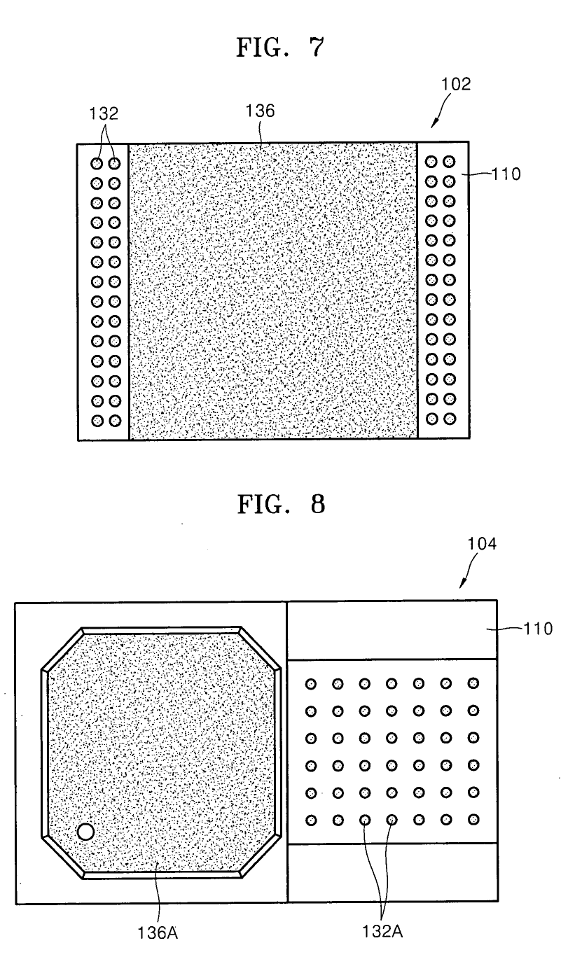

FIG. 7 is a plan view illustrating edges of the substrate 110 according to an example embodiment.

FIG. 8 is a plan view illustrating edges of the substrate 110 according to another example embodiment.

In the example embodiment of FIG. 7, each edge of the substrate 110 on which a sealing material 136 is formed may be folded. Solder balls 132 may be attached to the upper surfaces of the folded portions.

In the example embodiment of FIG. 8, only one edge of the substrate 110 may be folded. That is, a sealing material 136A may be formed on a left side of the substrate, and a right edge of the substrate 110 may be partially folded. Solder balls 132A may be formed on the upper surface of the folded portion. Further, in another example embodiment, the folding of the substrate 110 as shown in FIG. 7 may be modified to a structure in which right and left and up and down edges of the substrate 110 may be folded about the sealing materials 136 and 136A, which correspond to a body of the package.

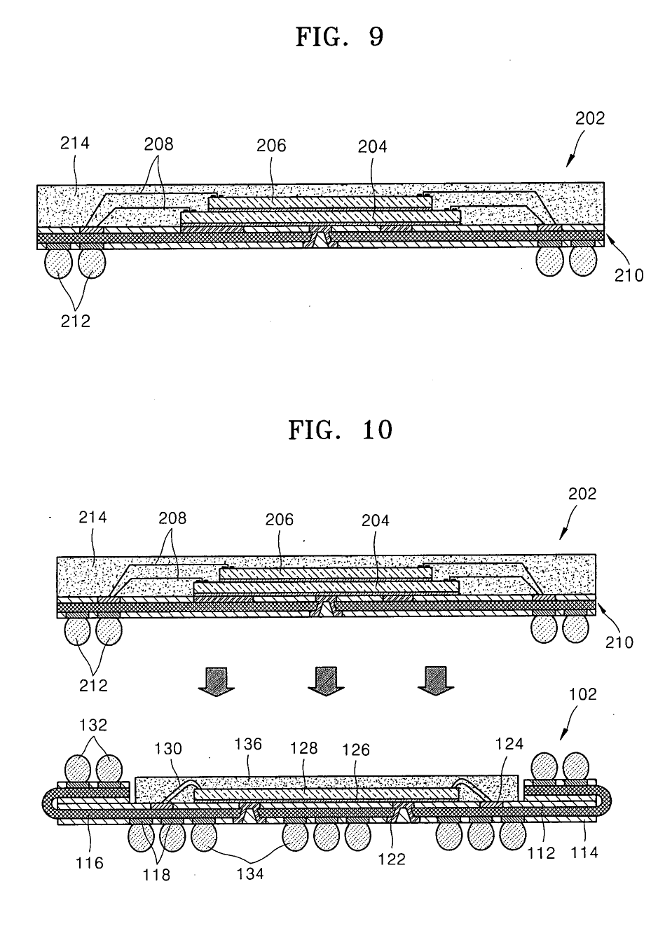

FIG. 9 is a sectional view illustrating an upper semiconductor package in a POP according to another example embodiment.

In the example embodiment of FIG. 9, an upper semiconductor package 202 may include a substrate 210 on which a printed circuit pattern may be formed, semiconductor chips 204 and 206 mounted on the substrate 210 and connected through a wire 208, a sealing resin 214 sealing the semiconductor chips 204 and 206, the wire 208, and the surface of the substrate 210 and solder balls 212 formed on a lower surface of the substrate 210 and connected to folded portions of the substrate 110 of the lower semiconductor package 102 (e.g., see FIG. 6).

In the example embodiment of FIG. 9, in an example, the substrate 210 may be either a rigid substrate or a flexible substrate. Further, in another example, the semiconductor chips 204 and 206 may be configured to perform memory functions, and only one chip may be mounted, or two or more semiconductor chips may be stacked.

In the example embodiments of FIGS. 10 and 11, a POP 100 may be fabricated by stacking the upper semiconductor package of FIG. 9 on the lower semiconductor package 102 of FIG. 6. In an example, the solder balls 132 attached to the folded portions of the substrate 110 of the lower semiconductor package 102 may be connected to the solder balls 212 attached on the lower surface of the substrate 210 of the upper semiconductor package 202 (e.g., see 138 of FIG. 11). Thus, because the solder balls 132 may be formed in the lower semiconductor package 102, a solder non-wet defect, which may occur during the connection of the two semiconductor packages 102 and 202, may be reduced and/or prevented. Although a warpage defect may occur to a limited degree on the upper and lower semiconductor packages 102 and 202, the warpage defect may be reduced due to the connection of two solder balls 132 and 212, and thereby an occurrence of the solder non-wet defect may likewise be reduced.

Hereinafter, example structure of a POP configured to reduce an occurrence of non-wet defects according to an example embodiment will be described with reference to FIG. 11.

In the example embodiment of FIG. 11, a POP 100 may include the substrate 110 (e.g., a flexible substrate, etc.), edges of which may be folded to attach the folded portions to each other and in which photo solder resist 112 and 114 need not be formed on the folded portions, the semiconductor chip 128 mounted on the substrate 110 and connected to the substrate 110 through the wire 130, the sealing resin 136 sealing the semiconductor chip 128 and the wire 130 except for the folded portions of the substrate 110 and solder balls 134 attached to a lower surface of the substrate.

In the example embodiment of FIG. 11, the POP 100 may further include a substrate 210 on which printed circuit patterns may be formed, semiconductor chips 204 and 206 mounted on the substrate 210 and connected through the wire 208, a sealing resin 214 sealing the semiconductor chips 204 and 206, the wire 208, and the surface of the substrate 210 and solder balls 212 attached to a lower surface of the substrate and connected to the folded portions of the substrate of the lower semiconductor package 102.

In the example embodiment of FIG. 11, each of the solder balls 212 of the upper semiconductor package 202, and each of the solder balls 132 disposed on the folded portions of the substrate 110 of the lower semiconductor package 102 may be attached such that two solder balls may be connected (e.g., see 138 of FIG. 11). Thus, the example semiconductor package may be able to handle an increase to a thickness of the lower semiconductor package 102.

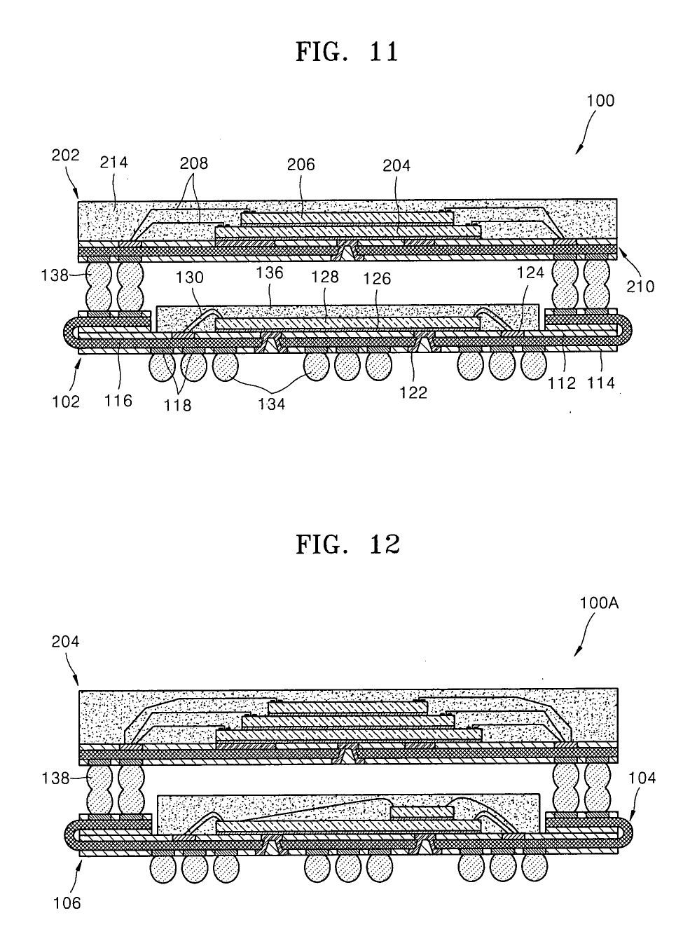

FIG. 12 is a sectional view illustrating a modification to the example structure of FIG. 11 according to another example embodiment.

In the example embodiment of FIG. 12, an additional semiconductor chip may be added to the lower semiconductor package 104 as shown in FIG. 11. For example, if another semiconductor chip having an RF function is added on the semiconductor chip having a logic function, the lower semiconductor package 104 may become thicker. However, because the connection 138 may include two connected solder balls, the additional thickness may be accounted for. Further, while two semiconductor chips may be stacked in the upper semiconductor package shown in the example embodiment of FIG. 11, it will be appreciated that other example embodiments may be modified so as to stack more than two semiconductor chips in the upper semiconductor package 204 as shown in FIG. 12.

FIG. 13 is a sectional view illustrating a modification to the example structure of FIG. 6 according to another example embodiment.

In the example embodiment of FIG. 13, in a POP 102A, while the solder balls 132 may be attached to the folded portion of the substrate 110 as in FIG. 6, the upper semiconductor package 202 (e.g., see FIG. 11) may be attached to the lower semiconductor package without use of the solder balls attached to the folded portions. In an example, the structure of the example embodiment of FIG. 13 may be used if only one semiconductor chip 128 is included in the lower semiconductor package 102A, and the sealing material 136 need not be above a given thickness threshold (e.g., the sealing material 136 may be thinner).

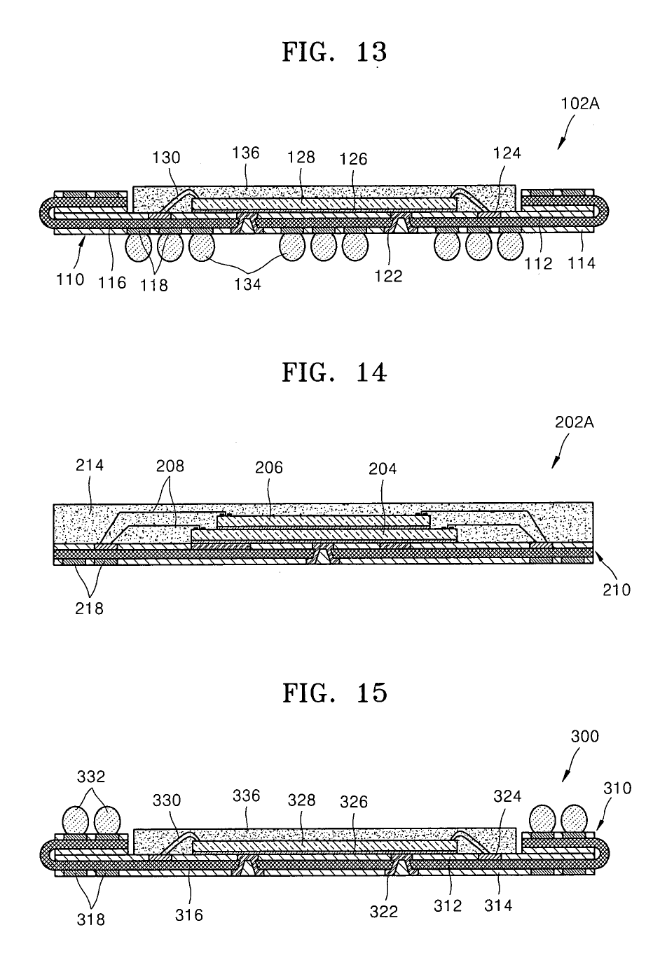

FIG. 14 is a sectional view illustrating a modification to the example structure of FIG. 9 according to another example embodiment.

In the example embodiment of FIG. 14, while solder balls may not be attached in the lower semiconductor package 102A as in FIG. 13, an upper semiconductor package 202A may be modified from the upper semiconductor package 202 of FIG. 9, without use of solder balls on a lower surface of the substrate 210 in the upper semiconductor package 202 of FIG. 9. In an example, the structure of the example embodiment of FIG. 14 may be used if a sealing material is relatively thin, for example, if only one semiconductor chip is used in the lower semiconductor package.

FIG. 15 is a sectional view illustrating a middle semiconductor package in a POP according to another example embodiment.

While above-described example embodiments have generally been limited to “upper” and “lower” semiconductor packages, it will be appreciated that one or more “middle” or intervening semiconductor packages may be interposed between the upper and lower semiconductor packages to form the POP, as will now be described with respect to the example embodiment of FIG. 15.

In the example embodiment of FIG. 15, the middle semiconductor package 300 may have a structure in which both edges of a substrate may be folded to attach folded portions of the substrate to non-folded “upper” portions of the same substrate, and the folded portions need not include photo solder resist 312 and 314. The middle semiconductor package 300 may include a flexible substrate 310, a semiconductor chip 328 mounted on the substrate 310 and connected to the substrate 310 through a wire 330, a sealing resin 336 sealing the semiconductor chip 328 on the substrate except for the folded portions of the substrate 310, and the wire 330, and solder balls 332 attached to the folded portions of the substrate 310 and connected to the solder balls of the upper semiconductor package.

In the example embodiment of FIG. 15, reference numeral 326 may denote an adhesive (e.g., liquid epoxy, adhesive tape, etc.), a reference numeral 322 may denote a through hole, a reference numeral 324 may denote a bond finger at a position where the wire is connected to the substrate, a reference numeral 316 may denote a substrate base, and a reference numeral 318 may denote a solder ball pad to which a solder ball formed in the semiconductor package is connected.

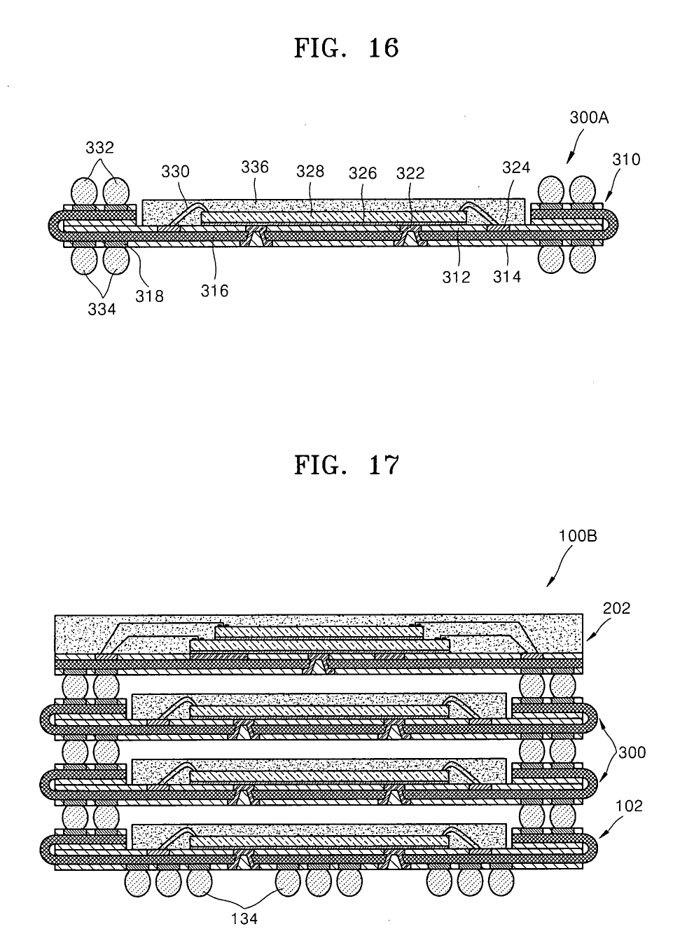

FIG. 16 is a sectional view illustrating a middle semiconductor package 300A according to another example embodiment.

In the example embodiment of FIG. 16, solder balls 334 may be attached to solder ball pads 318 disposed on a lower surface of a substrate 310. Because a height of a connection in the example embodiment of FIG. 16 may be increased as compared to the example embodiment of FIG. 16, the middle semiconductor package 300A may be used in conjunction with lower semiconductor package having higher thicknesses.

FIG. 17 is a sectional view illustrating a POP 100B according to another example embodiment.

In the example embodiment of FIG. 17, the POP 100B may include the lower semiconductor package 102 of FIG. 6, two middle semiconductor packages 300 of FIG. 15, and the upper semiconductor package 202 of FIG. 9 arranged in a vertical stacked. While the example embodiment of FIG. 17 illustrates two middle semiconductor packages 300, it will be appreciated that other example embodiments may include other types of middle semiconductor packages (e.g., middle semiconductor package 300A as in FIG. 16) and/or a different number of middle semiconductor packages (e.g., one, three, four, etc.).

In another example embodiment, a solder non-wet defect generated during stacking processes of the POP may be reduced or suppressed by the structure of the POP in which the substrate of the lower semiconductor package is at least partially folded. Likewise, a manufacturing cost may be reduced because the POP need not be retested after a detection of a solder non-wet defect (e.g., because an occurrence of such defects may be reduced).

Further, although the lower semiconductor package may include a plurality of semiconductor chips and the body may thereby become thicker, the solder balls formed on the folded portions of the lower semiconductor package and the solder balls attached to the lower surface of the upper semiconductor package may at least partially compensate the increase of the size of the POP (e.g., more “buffer” room may be present between respective semiconductor packages within the stack due to the solder balls). Further, in another example, because PSR need not be formed on the folded portions of the substrate in the lower semiconductor package, PSR may not crack in proximity to the folded portions, such that moisture penetration of the folded portions of the substrate may be reduced.

Example embodiments being thus described, it will be obvious that the same may be varied in many ways. For example, while above-described example embodiments are generally directed to POPs, it will be appreciated that other example embodiments may be directed to any type of stacked semiconductor structure.

Such variations are not to be regarded as a departure from the spirit and scope of example embodiments, and all such modifications as would be obvious to one skilled in the art are intended to be included within the scope of the following claims.

What is claimed is:

1. A package on package (POP), comprising;
a first semiconductor package including a first substrate, the first substrate being a flexible substrate having at least one folded portion, a first semiconductor chip mounted on and electrically connected to the first substrate; and
a second semiconductor package including a second substrate, at least one second semiconductor chip mounted on and electrically connected to the first substrate, the first and second semiconductor packages being electrically connected between the at least one folded portion of the first substrate and a portion of the second substrate.

2. The POP of claim 1, wherein the first semiconductor package is a lower semiconductor package and the second semiconductor package is an upper semiconductor package.

3. The POP of claim 1, wherein the first semiconductor package is a middle semiconductor package and the second semiconductor package is an upper semiconductor package, the middle semiconductor package positioned between a lower semiconductor package and the upper semiconductor package.

4. The POP of claim 3, further comprising:
at least one additional middle semiconductor package positioned between the lower semiconductor package and the upper semiconductor package.

5. The POP of claim 1, wherein the second substrate is not folded.

6. The POP of claim 1, wherein the at least one folded portion includes first and second folded edges of the first substrate.

7. The POP of claim 1, wherein photo solder resist is not disposed on the at least one folded portion.

8. The POP of claim 1, wherein the first semiconductor chip and the first substrate are electrically connected via a wire.

9. The POP of claim 8, wherein the first semiconductor package includes a sealing resin sealing the first semiconductor chip and the wire on a surface of the first substrate other than the at least one folded portion of the first substrate.

10. The POP of claim 1, wherein the first and second semiconductor packages include solder balls attached to at least one of a lower surface of the second substrate, a lower surface of a non-folded portion of the first substrate and an upper surface of the at least one folded portion of the first substrate.

11. The POP of claim 10, wherein the solder balls are attached to the upper surface of the at least one folded portion and the lower surface of the second substrate so as to provide the electrical connection between the first and second semiconductor packages.

12. The POP of claim 11, wherein the solder balls further provide a physically supportive connection between the first and second semiconductor packages.

13. The POP of claim 1, wherein the second substrate includes printed circuit patterns.

14. The POP of claim 1, wherein the second semiconductor chip and the second substrate are electrically connected via a wire.

15. The POP of claim 14, wherein the second semiconductor package includes a sealing resin sealing the second semiconductor chip and the wire on a surface of the second substrate.

16. The POP of claim 1, wherein the first semiconductor package further includes a third semiconductor chip on the first semiconductor chip.

17. The POP of claim 1, wherein the at least one folded portion of the first substrate is attached to a non-folded portion of the first substrate with one of a non-conductive adhesive, an adhesive tape and a conductive liquid adhesive.

18. The POP of claim 1, wherein the second semiconductor package includes at least one additional semiconductor chip.

19. The POP of claim 1, wherein the at least one folded portion includes two folded edges of the first substrate.

20. The POP of claim 1, wherein the at least one folded portion includes one folded edge of the first substrate.

21. A method of fabricating a package on package (POP), comprising;
folding at least one portion of a first substrate within a first semiconductor package including a first semiconductor chip, the first substrate being a flexible substrate;
mounting a second semiconductor package on the first semiconductor package, the second semiconductor package including a second substrate and at least one second semiconductor chip; and
forming an electrical connection between the first and second semiconductor packages via the at least one folded portion of the first substrate and a portion of the second substrate.

22. The method of claim 21, wherein the second substrate is not folded.

23. The method of claim 21, wherein the electrical connection is provided via solder balls connected to a lower portion of the second substrate and an upper portion of the at least one folded portion of the first substrate.
